(19) United States
(12) Patent Application Publication
(10) Pub. No.: US 2026/0251706 A1
(43) Pub. Date: Aug. 27, 2026

(54) Debug Method for High Data Rate Physical Layer Interface

(71) Applicant: Microchip Technology Inc., Chandler, AZ (US)

(72) Inventors: Morgan Monks, Tempe, AZ (US); Colby Conner, Chandler, AZ (US)

(73) Assignee: Microchip Technology Inc., Chandler, AZ (US)

(21) Appl. No.: 19/416,270

(22) Filed: Dec. 11, 2025

Related U.S. Application Data
(60) Provisional application No. 63/763,950, filed on Feb. 27, 2025.

(51) Int. Cl. G01R 31/317

(52) U.S. Cl. CPC G01R 31/31705

(57) ABSTRACT

An integrated circuit is provided including a state machine including a multi-bit state variable and a single-bit state variable, the single-bit state variable representing a present state of a network physical interface, an encoder to encode the multi-bit state variable into a bit stream, a first selector for selecting to pass to an external state contact either the single-bit state variable or the bit stream based on a configuration value, and an external communications contact for transmitting or receiving network data.

### RELATED APPLICATIONS

This application claims priority to previously filed U.S. Provisional Patent Application Ser. No. 63/763,950, filed on Feb. 27, 2025, the contents of which are incorporated by reference in their entirety.

### FIELD OF THE INVENTION

This disclosure relates to debugging a high data rate physical layer interface circuit.

### SUMMARY

In some examples, an integrated circuit is provided comprising a state machine including a multi-bit state variable and a single-bit state variable, the single-bit state variable representing a present state of a network physical interface, an encoder to encode the multi-bit state variable into a bit stream, a first selector for selecting to pass to an external state contact either the single-bit state variable or the bit stream based on a configuration value, and an external communications contact for transmitting or receiving network data.

In some examples of the previous paragraph, the network is a single pair ethernet connection operable at or greater than a ten megabit per second data rate.

In some examples of one of the two previous paragraphs, the single bit state variable represents one of: an ethernet link status and an ethernet activity status and the external state contact is operable to control a light emitting diode (LED).

In some examples of one of the three previous paragraphs, the integrated circuit includes a second selector for selecting to pass to a second external state contact either a second single-bit state variable or a second multi-bit state variable encoded into a second bit stream.

In some examples of one of the four previous paragraphs, the multi-bit state variable provides information about an ethernet link training process to establish a network link between two single pair ethernet partners.

In some examples of one of the five previous paragraphs, the multi-bit state variable provides information about an equalization state machine for configuring an equalizer circuit to modify a transmission signal to be output on the external communications contact.

In some examples of one of the six previous paragraphs, the integrated circuit includes an interrupt signal pin.

In some examples, a method is provided including tracking state machine status information in a multi-bit state variable within an integrated circuit; encoding the multi-bit state variable into a bit stream; tracking a single-bit state variable, the single bit state variable representing a present state of a network physical interface; selecting the bit stream to output on a light emitting diode (LED) contact of the integrated circuit during a period of link startup; selecting the single-bit state variable to output on the first LED contact of the integrated circuit after the period of link startup; and alternately transmitting and receiving data on the network physical interface.

In some examples of one of the previous paragraph, the method includes, concurrently:
decoding the bit stream with one of: an oscilloscope, a digital logic analyzer, and a general-purpose input to a processor external to the integrated circuit; and observing a data signal on the network physical interface.

In some examples of one of the previous two paragraphs, the multi-bit state variable indicates one of: a current test pattern transmitted on the network physical interface and a current equalizer configuration and the single-bit state variable indicates one of: an ethernet link status and an ethernet activity status.

In some examples of one of the previous three paragraphs, the method includes encoding a second multi-bit state variable into a second bit stream; tracking a second single bit state variable, the second single bit state variable representing a second present state of the network physical interface; selecting the second bit stream to output on a second LED contact of the integrated circuit during the period of link startup; and selecting the second single-bit state variable to output on the second LED contact of the integrated circuit after the period of link startup.

In some examples of one of the previous four paragraphs, the second single-bit state variable represents one of: an ethernet link status and an ethernet activity status.

In some examples of one of the previous five paragraphs, the multi-bit state variable provides information about an ethernet link training process to establish a network link between two single pair ethernet partners.

In some examples of one of the previous six paragraphs, the method comprises driving an interrupt pin of the integrated circuit to initiate a debug mode of operation.

In some examples, a circuit is provided including an integrated circuit and a printed circuit board. The comprises a state machine including a multi-bit state variable and a single-bit state variable, the single-bit state variable representing a present state of a local area network (LAN) physical interface, an encoder to encode the multi-bit state variable into a bit stream, a first selector for selecting to pass to an external state pin either the single-bit state variable or the bit stream based on a configuration value, and an external pin for transmitting or receiving local area network (LAN) data. The printed circuit board comprises two contacts for connecting a light emitting diode (LED), the first contact coupled to the external state pin and the second contact coupled to a resistor, and a network connector communicatively coupled to the external pin for transmitting or receiving LAN data.

In some examples of the previous paragraph, the first contact is coupled to a digital logic analyzer for decoding the bit stream.

In some examples of one of the previous two paragraphs, the single bit state variable represents one of: an ethernet link status and an ethernet activity status.

In some examples of one of the previous three paragraphs, the integrated circuit comprises a second selector for selecting to pass to a second external state pin either an output of the first selector or an operational status indicator to an external pin based on a second configuration value.

In some examples of one of the previous four paragraphs the second external state pin is operable to control a light emitting diode (LED) indicating one of: an ethernet link status and an ethernet activity status.

In some examples of one of the previous five paragraphs, the multi-bit state variable provides information about an ethernet link training process to establish a network link between two single pair ethernet partners.

### BACKGROUND

A single pair ethernet physical layer interface (PHY) may operate at data rates exceeding 100 Mbps, 1 Gbps, or higher speeds. The network protocol has a complex training process wherein two PHYs negotiate settings to arrive at functional communications over a wiring harness. This training process may be performed any time the PHY starts up unless the PHY was in a designated sleep sate. Communications stability may be critical in some applications as the network may be carrying data related to sensors that may sense a car collision or other safety event that requires real-time processing and immediate action by safety systems such as airbags, seatbelt pretensioners, or automatic braking systems. This negotiation may have a hard deadline of 100 ms, which may be validated by certification authorities. If the negotiation cannot complete within that deadline, debugging may be required to adjust settings or the design. One approach is to interpose a logic analyzer on the line. This approach alters the impedance of the network medium and therefore alters the training. This approach also requires expensive high-speed monitoring equipment.

### BRIEF DESCRIPTION OF THE FIGURES

FIG. 1 illustrates a circuit for debugging a PHY using a repurposed input/output contact, according to certain examples.

FIG. 2 illustrates a circuit for debugging a PHY using three repurposed input/output contacts, according to certain examples.

FIG. 3 illustrates a timing diagram, according to certain examples.

FIG. 4 illustrates another circuit for debugging a PHY using repurposed input/output contacts, according to certain examples.

FIG. 5 illustrates system for debugging a PHY using repurposed input/output contacts with an external signal reader, according to certain examples.

FIGS. 6A and 6B illustrate alternative arrangements of another circuit for debugging a PHY using a repurposed input/output contact, according to certain examples.

FIG. 7 illustrates a method for debugging a PHY, according to certain examples.

FIG. 8 illustrates a printed circuit board for debugging a PHY using a repurposed input/output contact, according to certain examples.

FIG. 9 illustrates another printed circuit board for debugging a PHY using a repurposed input/output contact, according to certain examples.

FIG. 10 illustrates another method for debugging a PHY, according to certain examples.

FIG. 11 illustrates another method for debugging a PHY, according to certain examples.

### DETAILED DESCRIPTION

In some examples, the outputs on a single pair ethernet (SPE) PHY may be redefined to allow observation of state machine variables during PHY configuration. Each state machine state outputs may be encoded into a single bit output that may be observed with a digital storage oscilloscope (DSO), digital logic analyzer, or processor board with general-purpose input/output contacts. The implementation may be accomplished in standard cells. Software register access using MDIO/MDC may configure the I/O redefinition and the source of debug signals. This approach may allow debugging of a reference board or even a production package and may be performed in customer-designed PCB modules with minimal PCB modification in the field. The PCB modification may be reversable to allow nondestructive debugging of production modules. In some examples, the existing LEDs may be used to optically signal internal state information to an external optical reading device. In some examples, the outputs on a network PHY may be redefined to allow observation of state machine variables at any time using high-speed switching and a light reception circuit on a monitoring device. In some examples, this approach may be used to debug connection information in other high speed network environments such as an optical fiber media converter.

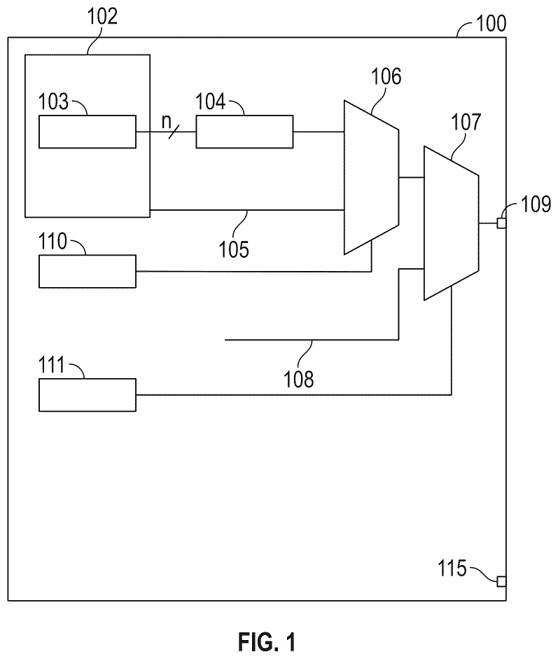

FIG. 1 illustrates a circuit for debugging a PHY using a repurposed input/output contact, according to certain examples. Integrated circuit 101 may include input/output contact 109 that may be connected to an LED under normal operation and connected to a logic analyzer during a debug operation. Integrated circuit 101 may include state machine 102 for performing the training protocol to establish communications over a data network via communication line contact(s) 115. State machine 102 may include multi-bit state register 103 and generate state output 105. Encoder 104 may encode the value of the bits of state register 103 into a shaped pulse that may be carried on single line. Selector 106 may select the encoded output generated by encoder 104 or state output 105 to pass through to selector 107 based on the value of configuration register 110. Selector 107 may select the output of selector 106 or LED control signal 108 based on the value of configuration register 111. The output of selector 107 may be passed to an I/O contact of integrated circuit 101 and exposed to a printed circuit board (PCB). Bandwidth of an I/O contact such as an LED driver may be approximately 25 MHz, which may be sufficient to provide sufficient granularity to indicate the timing of state machine transitions and the status of state machine variables before and after state machine transitions.

In some examples, integrated circuit 101 may be soldered to a PCB as part of a network adapter module to allow some function to communicate over a network. For example, the PCB may include a video display driver of a head unit in an automobile coupled to integrated circuit 101 to allow receipt of a stream of video data over an ethernet communications link to be received and displayed on the head unit. In some examples, integrated circuit 101 may be connected to the PCB by soldering input/output contact 109 and contacts for communication line contact(s) 115 to the PCB. In some examples, these contacts may be ball pads, wire leads, pins, or other packaging contacts. In some examples input/output contact 109 may be underneath integrated circuit 101 and inaccessible to a debug probe after IC 101 has been mounted to the PCB.

In some examples, state machine 102 may be implemented in software instructions stored on a non-transitory computer readable memory and executing on a processor within integrated circuit 101. In some examples, state machine 102 may be implemented in logic within integrated circuit 101. In some examples, state machine 102 may be implemented with a combination of hardware and software. In some examples, state machine 102 may transition through various states to perform a network link setup and configuration over network communication lines (exposed at communication line contact(s) 115) with one or more nodes external to integrated circuit 101. In some examples, the network link complies with the XBASE-T1 (Single-Pair Ethernet) protocol standard such as the 10BASE-T1, 100BASE-T1, 1000BASE-T1, or NGBASE-T1 standards. In some examples, the network link complies with the IEEE 802.3cg, IEEE 802.3bw, IEEE 802.3bp, or IEEE 802.3ch standards. In some examples, the 1000BASE-T1 physical interface (PHY) within integrated circuit 101 performs a synchronization method and start-up process. State machine 102 may transition between states including (but not limited to) reset/silent, clock synchronization, half-duplex training, and send idle/data. Each of those states may include additional states.

In some examples, clock synchronization may require generation and transmission by the first PHY of a first symbol (e.g., wave form or bit pattern) followed by a second symbol. In some examples, clock synchronization may also require receipt and processing of symbols received from a second PHY. One or more state variables may control the sequence of operations required to perform this synchronization process.

In some examples, half-duplex training (HDX TRAINING) involves a first PHY and a second PHY taking turns sending and receiving messages in a coordinated manner. This exchange of messages may allow negotiation of the link speed and configuration, including error correction parameters. One or more state variables may control the sequence of operations required to perform this training process. In some examples, link training may include a synchronization process.

If successful, state machine 102 may establish an ethernet link in a matter of milliseconds, with some state machine transitions occurring within a few microseconds. An engineer may desire to observe state values and transition timing on production parts to aid in debugging failures or to assist in reprogramming a state machine to improve robustness. In some examples, an engineer may wish to observe state values during data transfer to debug data transfer errors.

In some examples, encoder 104 may encode a multi-bit value by modulating the pulse width, alternating values at a higher clock rate, assigning intermediate voltages between zero and V_{dd}, or other encoding techniques. Encoder 104 may receive as input n bits of a multi-bit state value and generate an output on a single line. In some examples, multiple encoders 104 may be provided to encode other multi-bit state values. In some examples, a single encoder 104 may be provided on the output of a multi-bit selector that allows the circuit to select one of many multi-bit state variables to encode. In some examples, encoder 104 may include a start bit or other symbol to facilitate interpretation of encoded values by an external debugger. The start bit can aid with synchronizing the receiver with the timing of the encoded value. In some examples, encoder 104 may include a stop bit to further facilitate interpretation of encoded values.

In some examples, state output 105 may be a link status state value for an ethernet network link including communication line(s) 115. In steady state operation, state output 105 may be routed through selectors 106 and 107 to input/output contact 109 to drive an LED that indicates to a user the status of the ethernet link. In some examples, state output 105 may be a link activity value for an ethernet network link. This link activity value may indicate active output or reception of network data over communications line(s) 115. In some examples, a second input/output contact is provided so integrated circuit 100 can drive a link status and a link activity indicator in normal operation. In these examples, input/output contact 109 for one or both of the link status and link activity indicators may be used to provide visibility into state variables and transition timing.

In some examples, selectors 107 and 107 may be multiplexors (MUXes). In some examples, selector input 108 may be driven by a configuration register that may be set with logic or software instructions placing the circuit in a debug mode. In some examples, an external input signal may trigger a processor within integrated circuit 101 to reset state machine 102 and set the configuration register to pass state machine values to input/output contact 109. In some examples, configuration register 110 may select with state machine variable of state machine 102 will be passed by selector 106. In some examples, configuration register 110 may be set by the processor, not shown, as state machine 102 transitions to a new state. In some examples, state machine 102 may set configuration register 110 as part of its state transitions.

In some examples, input/output contact 109 may be operable to sink sufficient current to drive an external LED coupled through a pullup resistor to a Vdd source. Input/output contact 109 may be used as an output only to drive the external LED. The external LED may, for example, indicate a connection status of the communications network physical link (e.g., formed at least in part by communications line(s) 115).

In some examples, communication line(s) 115 may form a matched transmission pair such as a single pair ethernet connection. In some examples, communication line(s) 115 may connect to a common mode choke on a printed circuit board (PCB) that connects to a coupler for coupling a single twisted pair cable. In some examples, communication line(s) may drive any type of network transceiver. In some examples, communication line(s) 115 may drive a single ethernet transceiver. In some examples, communication line(s) may drive an optical interface to a fiber optical cable. This approach does not require media line taps that may alter the impedance of the media and may require an expensive digital storage oscilloscope (DSO) and post capture analysis software. FPGA emulation of the PHY is not possible at these data rates. Some examples presented here provide a way to debug a PHY without increasing contact count to allow parallel debugging. Increasing contact count would lower profit margins for the IC manufacturer and customer as integration costs would also increase. Examples presented not require on-chip capacitors needed for SSO, which allows for decreased die size and production costs. Debugging by cut and try methods, e.g., trying different register combinations in hopes of solving a training error or training timing error, are slow and tedious. Debugging with data allows identification of the root cause of issues rather than eliminating possible problems. In addition, visibility into the speed at which training completes may provide a measure of the robustness of the PHY configuration.

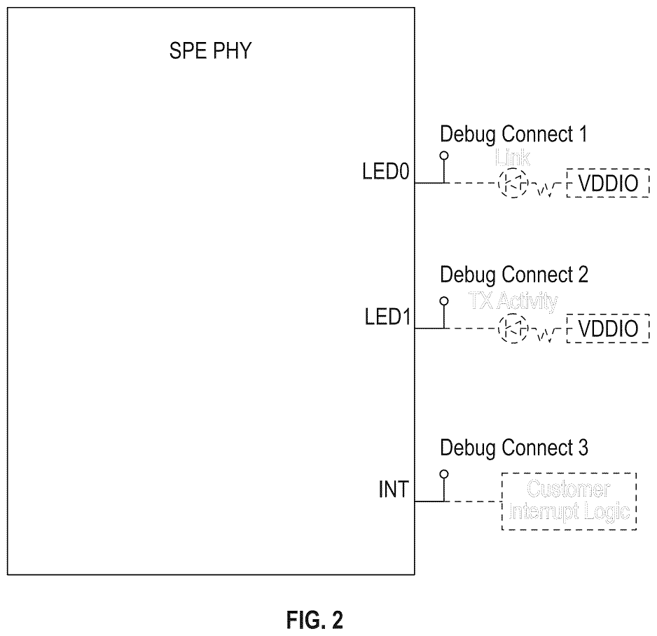

FIG. 2 illustrates a circuit for debugging a PHY using three repurposed input/output contacts, according to certain examples. In some examples, PCB 200 includes integrated circuit 201, LEDs 231 and 233, pull down resistors 232 and 234, and customer interrupt logic 235. Integrated circuit 201 may be a single pair ethernet (SPE) physical layer transceiver (PHY) with transceiver contacts 215p and 215n, LED0 driver contact 209, LED1 driver contact 219, and interrupt input contact 229. In some examples, an engineer may remove LEDs 231 and 233 and connect oscilloscope leads to LED0 driver contact 209 and LED1 driver contact 219 to monitor signals on those contacts. In some examples, customer interrupt logic 235 may be disconnected and interrupt input contact 229 may be driven by the engineer to force the PHY into a debug mode.

In this example, SPE PHY may be configured for operational mode with LED0 driver contact 209 may be connected to LED 231 for indicating the network link status. LED1 driver contact 219 may be connected to LED 233 for indicating transmit activity over the network link. And interrupt input contact 229 may be connected to customer interrupt logic 235 to receive an interrupt signal (INT) from customer interrupt logic 235. Each contact 209, 219, and 229 may be a general purpose input/output (GPIO) interface to integrated circuit 201. In some examples, an interrupt signal (INT) received at interrupt input contact 229 may cause the integrated circuit 201 to read the values at all three contacts (209, 219, and 229). If LEDs 231 and 233 are in place along with pull-up resistors 232 and 234, integrated circuit 201 may read three bits of data as 111₂ and interpret the interrupt as an operational interrupt from customer interrupt logic 235.

When field debugging, LEDs 231 and 233 and customer interrupt logic 235 may be disconnected. In some examples, an interrupt signal (INT) received at interrupt input contact 229 may cause the integrated circuit 201 to read the values at all three contacts (209, 219, and 229). With LEDs removed, LED contacts 209 and 219 may be effectively grounded by internal pull-down resisters (not shown), integrated circuit 201 may read three bits of data as 001₂ or 100₂ and interpret the interrupt as an input from a field engineer. Integrated circuit 201 may then switch into a debug mode of operation, which may include setting configuration register 110 accordingly to allow passing of the encoded state variable data through to LED contacts 209 and 219. In some examples, LED contacts 209 and 219 may be probed with an oscilloscope to read the encoded state variable data.

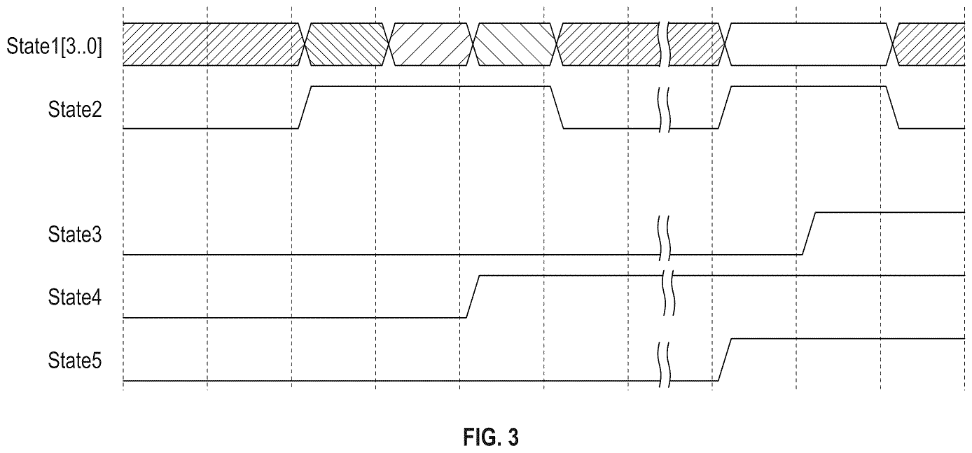

FIG. 3 illustrates timing diagram, according to certain examples. Timing diagram 300 illustrates values over time for multi-bit state variable state1 and four single bit state variables: state2, state3, state4, and state5. Timing diagram 300 shows these values at regular time intervals 320 that align with a clock pulse in some examples.

An engineer may configure integrated circuit 101 (e.g., by setting values in configuration register 110) to select one or more states of state machine 102 to observe during a debugging process. A multi-bit state value such as state1[3 . . . 0] may be encoded on a single output contact in some examples. In some examples, multiple state outputs such as {state2, state3, state4} may be encoded together on a single output contact. In some examples, a single state output such as state 5 may be passed to an output contact. In some examples, state1 may not have a valid value or its value may be unimportant to a debugging process for certain periods of time, such as at times 302 and 306. In some examples, values from other state variables may be output at times 302 and 306 while state1 has no value of interest. In some examples, the state machine may select an encoded value of state1 at times 303 and 304. In some examples, the encoder may continuously and repeatably output the encoded value of state1 at each time interval 320. In other examples, the encoder may output the encoded value of state1 one time and during the first time interval 320 when the value transitions.

In some examples, a multi-bit state variable may identify a current test pattern being transmitted on the network physical interface. For example, the state machine may transmit a SEND_Z signal for some period of time, which is the transmission of all zeros. The state machine may then transmit a SEND_I signal, which is an idle signal and represents more power than zeros, but not full power. The state machine may then refine timing, equalizer, and scrambler settings. Later, the state machine may generate a SEND_N signal, which is the transmission of data or idle signals. In some examples, the state machine may sequentially encode as bit streams timing values, equalizer values, and/or scrambler settings and send those bit streams to the LED contact for external decoding. Equalizer values may be used to configure an equalizer circuit that can reform signals degraded due to phenomena such as long cables, high frequences, far end crosstalk, noise, electromagnetic interference, and other channel impairments. Examples of equalizers include linear equalizers, decision feedback equalizers, and multi-dimensional equalizers.

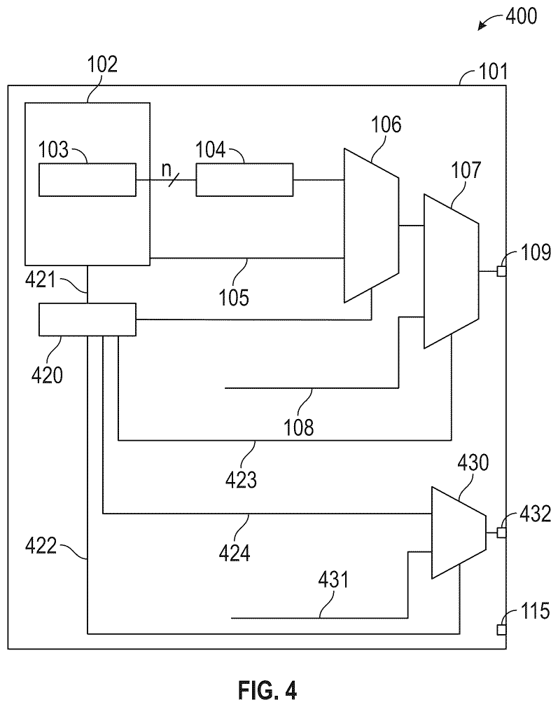

FIG. 4 illustrates a circuit for debugging a PHY using repurposed input/output contacts, according to certain examples. Circuit 400 includes input/output contacts 109 and 432 in addition to communication line contact(s) 115. In some examples, debug state machine 420 provides active control of selector control line 108 that selects the output of selector 106. In some examples, debug state machine 420 provides active control of selector control line 423 that selects the output of selector 107. In some examples, debug state machine 420 provides active control of selector control line 422 that selects the output of selector 430. In some examples, state output 105 may be a link activity value for an ethernet network link. This link activity value may indicate active transmission of network data through communications line contacts(s) 115. In some examples, state output 431 provides a link status value for the ethernet network link. In some examples, debug state machine variable 424 may be m bits wide and may represent a current state of debug state machine 420. Encoder 444 may encode the m-bit value to output on contact 432 when selected by selector control line 422. In some examples, n and m may be the same.

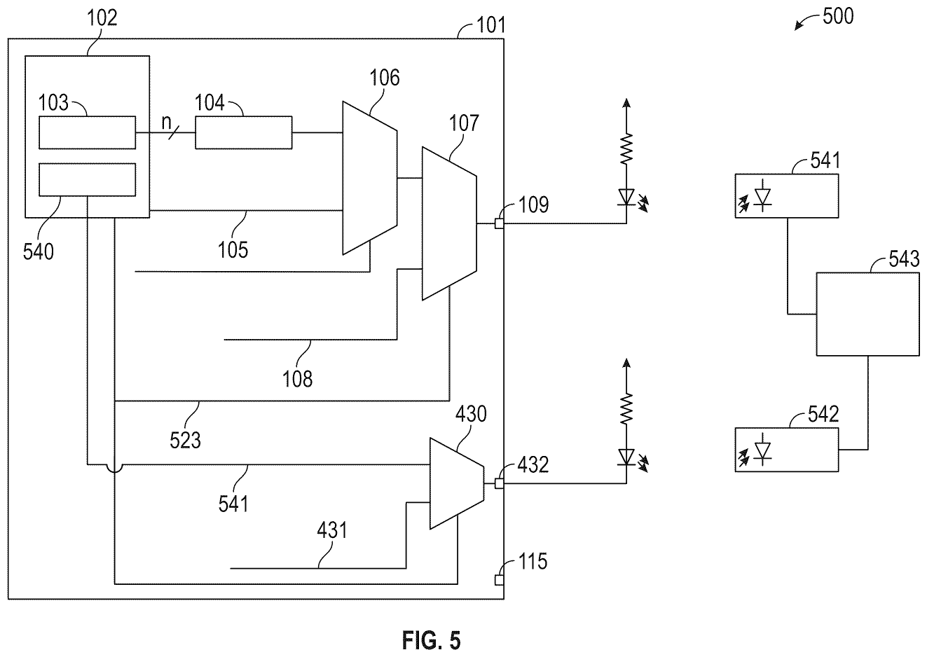

FIG. 5 illustrates a system for debugging a PHY using repurposed input/output contacts with an external signal reader, according to certain examples. In some examples, state machine 102 operates in a link setup mode and an operation mode and outputs debug information during link setup mode. System 500 includes PCB 501 and reader device 502. PCB 501 may include IC 101 with input/output contact 109 coupled to LED 561 and pull-up resistor 562, and input/output contact 432 coupled to LED 563 and pull-up resistor 564. In an operation mode, control selector 523 may be asserted by state machine 102 to pass link status value 105 to LED 561 and to pass link activity value 432 to LED 563. In a link setup mode, control selector 523 may be unasserted by state machine 102 to pass multi-bit state variable 103 (encoded by encoder 104) to LED 561 and to pass state variable 540 to LED 563. Because the link setup mode may be as short as a few seconds, this temporary flickering of the link activity and link status LEDs may not be noticeable to operators (e.g., vehicle mechanics and diagnosticians) or at least might be readily explainable in a diagnostic manual. Reader device 502 may include processor 543 and optical sensors 541 and 542. In some examples, optical sensors may be photoresistors or phototransistors. Reader device 502 may be programmed to decode and output multi-bit values. In some examples, reader device 502 may further interpret the decoded state variables and assist with debugging the link setup process. In some examples, additional circuitry (not shown) may be added to the output of selectors 107 and 430 to reverse the polarity of the output in link setup mode. In this approach, LEDs 561 and 563 may be bi-color LEDs to allow link debugging information to be displayed in a different color than link status and link activity information. In some examples, the second color may be infrared.

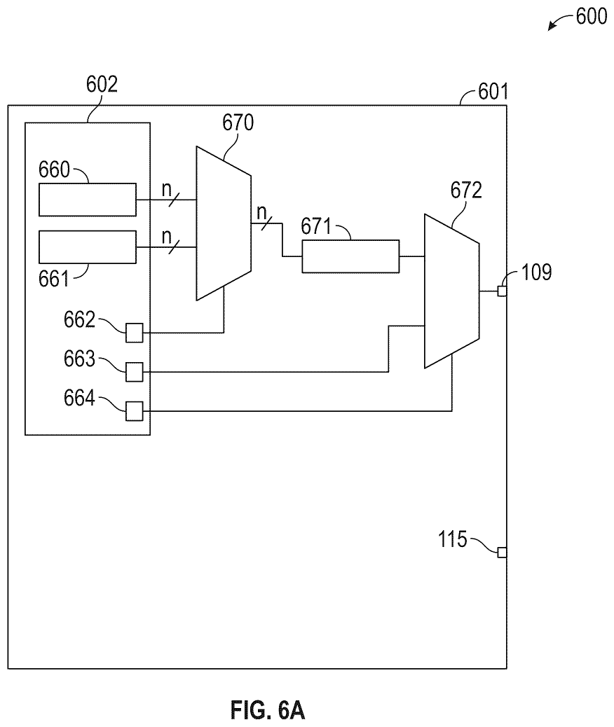

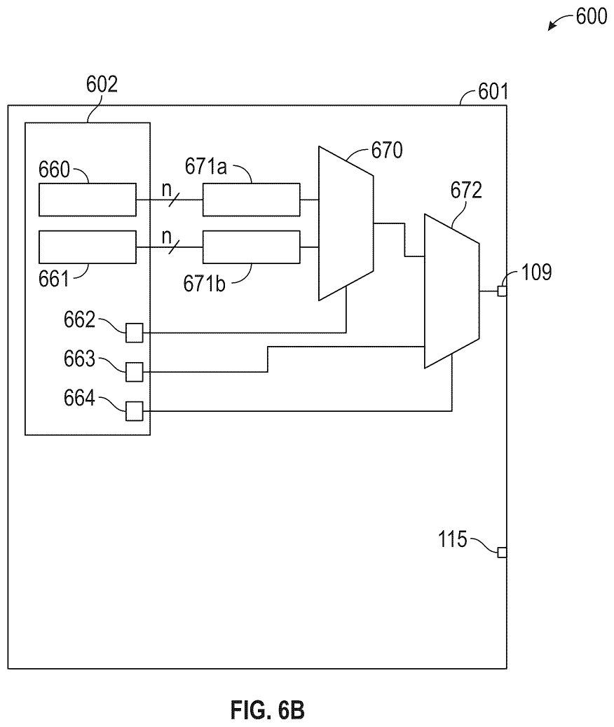

FIG. 6A illustrates another circuit for debugging a PHY using a repurposed input/output contact, according to certain examples. Integrated circuit 600 includes state machine 601 with multi-bit state variables 660 and 661 and single-bit state variable 663. State machine 601 also includes debug variable selector control 662 and debug mode selector control 664. Integrated circuit 600 includes debug variable selector 670, encoder 671, and debug mode selector 672 with an output to externally accessible input/output contact 109. Integrated circuit 600 also includes one or more communications network contacts 115. In some examples, debug variable selector 670 may select from two or more multi-bit variables to pass to encoder 671 for encoding to a single bit path.

FIG. 6B illustrates another circuit for debugging a PHY using a repurposed input/output contact, according to certain examples. In this example, debug selector 670 receives single-bit representations of state variables to pass to debug mode selector 672. Multi-bit state variable 660 passes n bits of state variable data to encoder 671a to be encoded into a bit stream. Multi-bit state variable 661 passes m bits of state variable data to encoder 671b to be encoded into a bit stream. In some examples, n equals m.

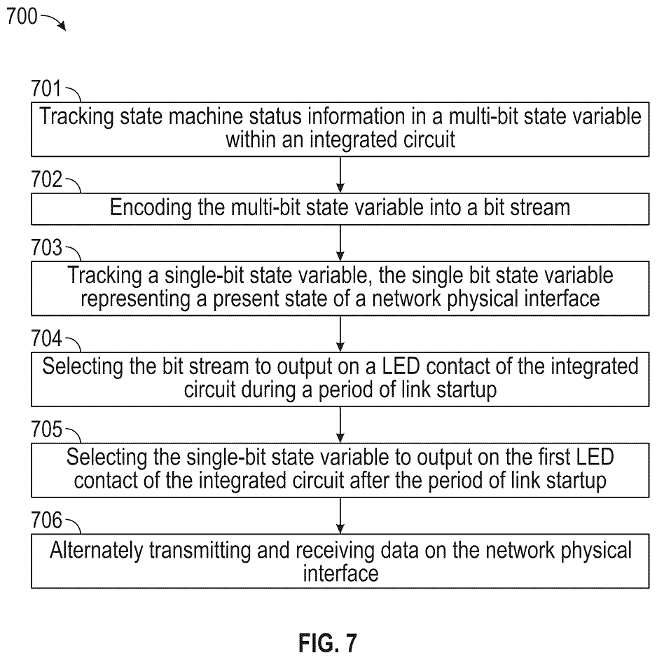

FIG. 7 illustrates a method for debugging a PHY, according to certain examples. Method 700 begins at block 701 by tracking state machine status information in a multi-bit state variable within an integrated circuit. In some examples, more than one multi-bit state variables may represent the current state of the state machine. At block 702, the method continues by encoding the multi-bit state variable into a bit stream. At block 703, the method continues by tracking a single-bit state variable, the single bit state variable representing a present state of a network physical interface. In some examples, the present state of the network PHY may be a link status value. In some examples, the present state of the network PHY may be a transmit activity value. At block 704, the method continues by selecting the bit stream to output on a light emitting diode (LED) contact of the integrated circuit during a period of link startup. At block 705, the method continues by selecting the single-bit state variable to output on the first LED pad of the integrated circuit after the period of link startup. At block 706, the method continues by alternately transmitting and receiving data on the network physical interface.

In some examples, the method includes determining the absence of an LED connected to the LED contact and entering a debug mode. In some examples, the method includes receiving an interrupt and entering a debug mode. In some examples, the method includes, once a network link has been established, exiting the debug mode. In some examples, the method includes selecting the single bit state variable to output on the LED contact. In some examples, the method includes tracking state machine status information in a second multi-bit state variable within the integrated circuit and encoding the second multi-bit state variable into a second bit stream.

In some examples, the method includes concurrently decoding the bit stream at the LED contact while observing a data signal on the network physical interface. In some examples, the decoding may be performed by an oscilloscope or a digital logic analyzer. In some examples, the decoding may be performed by connecting a general purpose input pin of a processor external to the integrated circuit and observing the bit stream. The network physical interface may be observed with an oscilloscope.

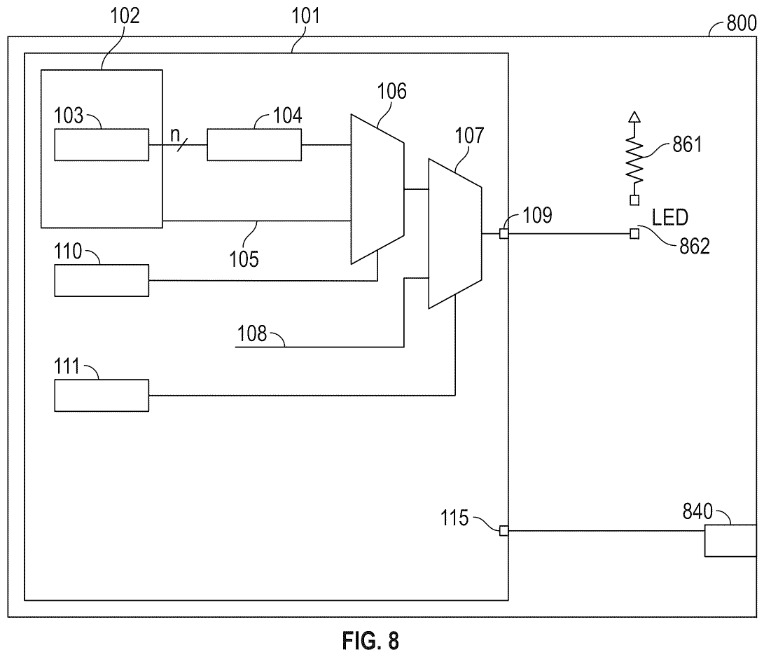

FIG. 8 illustrates a printed circuit board for debugging a PHY using a repurposed input/output contact, according to certain examples. PCB 800 may include integrated circuit 101, LED location 862, resistor 861 and network connector 840. In some examples, LED location 862 includes two solder pads, one connected to a pad corresponding input/output contact 109 of integrated circuit 101 and the other connected to one end of resistor 861. In some examples, an LED is soldered to the two solder pads at LED location 862. In some examples, resistor 861 is a pullup resistor that is also connected to a power source, such as V_{dd}. In some examples, resistor 861 is a pulldown resistor that is also connected to ground. In some examples, network connector 840 may be a screw terminal that accepts a wire from a network cable. In some examples, network connector 840 may be a media converter for translating electrical signals to optical signals and vice versa. In some examples, network connector 840 may including a connector for coupling a cable shield to a ground plane on PCB 800 and may include two connectors for connecting to a single pair of network lines in the network cable.

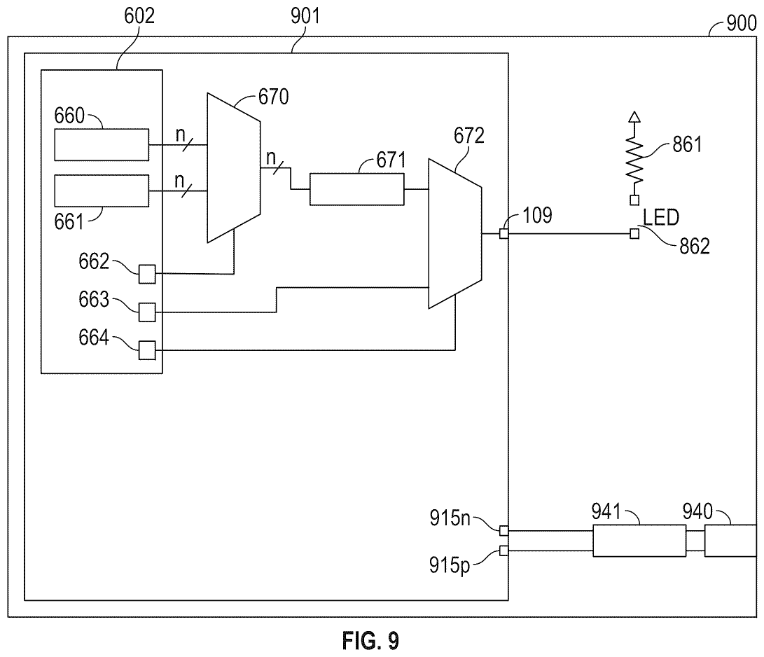

FIG. 9 illustrates another printed circuit board for debugging a PHY using a repurposed input/output contact, according to certain examples. PCB 900 may include integrated circuit 901, LED location 862, resistor 861, choke 941, and network connector 940. In some examples, integrated circuit 901 includes the components of integrated 601 (discussed previously) with two communication line contacts 915n and 915p that make up a differential pair with a negative (915n) and a positive (915p) line. This differential pair may be connected through common mode choke 941 to network connector 940. Common mode choke 941 may suppress common mode noise while allowing the differential signal to pass.

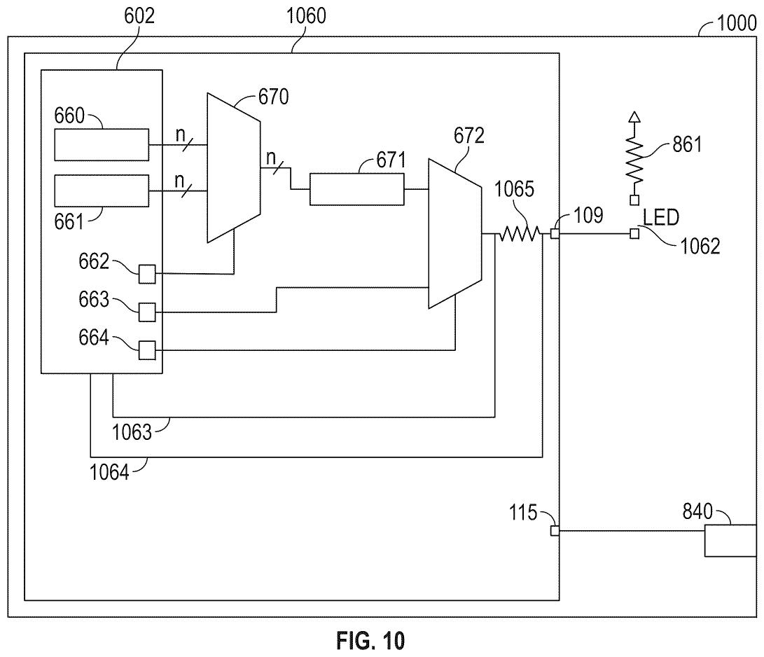

FIG. 10 illustrates another printed circuit board for debugging a PHY using a repurposed input/output contact the PCB having an internal sensor, according to certain examples. PCB 1000 may include integrated circuit 1060, LED location 862, resistor 861, and network connector 840. Integrated circuit 1060 includes the components of integrated circuit 601 with the addition of sense resistor 1065 and sense lines 1063 and 1064. In some examples, state machine 602 may be programmed to temporarily output a logical zero at input/output contact 109. If no LED is connected at LED location 862, no current will flow through 1065 and no voltage differential will exist between sense lines 1063 and 1064. Sensing no current with a zero output at input/output contact 109, state machine 602 may enter a debug mode and set state variable 664 to select an encoded multi-bit state value to output to input/output contact 109. If an LED is connected at LED location 862 when the output is a logical zero at input/output contact 109, measurable current will flow through sense resistor 1065 and will result in a voltage differential between sense lines 1063 and 1064. State machine 602 may exit the debug mode and change the value of state variable 664 to route single-bit state variable 663 (which may be a link status or link activity indicator) to input/output contact 109.

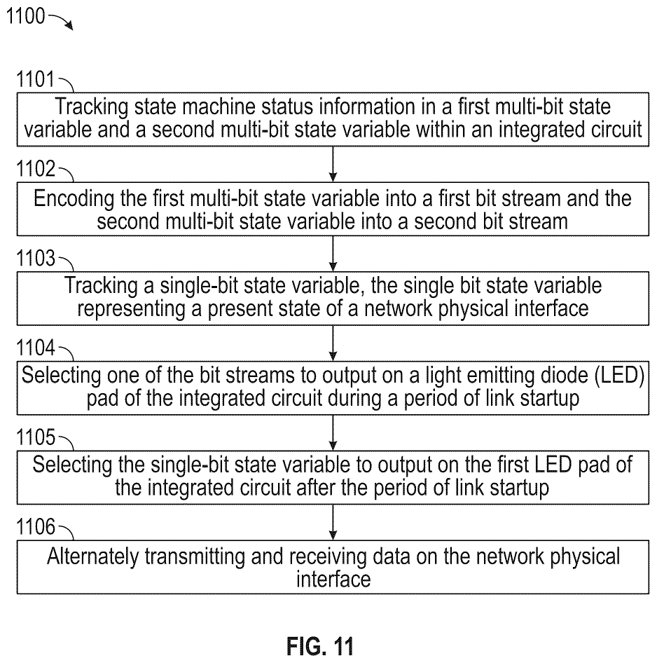

FIG. 11 illustrates another method for debugging a PHY, according to certain examples. At block 1101, the method begins by tracking state machine status information in a first multi-bit state variable and a second multi-bit state variable within an integrated circuit. At block 1102, the method continues by encoding the first multi-bit state variable into a first bit stream and the second multi-bit state variable into a second bit stream. At block 1103, the method continues by tracking a single-bit state variable, the single bit state variable representing a present state of a network physical interface. At block 1104, the method continues by selecting one of the bit streams to output on a light emitting diode (LED) pad of the integrated circuit during a period of link startup. At block 1105, the method continues by selecting the single-bit state variable to output on the first LED pad of the integrated circuit after the period of link startup. At block 1106, the method continues by alternately transmitting and receiving data on the network physical interface.

Although examples have been described above, other variations and examples may be made from this disclosure without departing from the spirit and scope of these examples.

We claim:

1. An integrated circuit comprising:
a state machine including a multi-bit state variable and a single-bit state variable, the single-bit state variable representing a present state of a network physical interface,
an encoder to encode the multi-bit state variable into a bit stream,
a first selector for selecting to pass to an external state contact either the single-bit state variable or the bit stream based on a configuration value, and
an external communications contact for transmitting or receiving network data.

2. The integrated circuit of claim 1, wherein the network is a single pair ethernet connection operable at or greater than a ten megabit per second data rate.

3. The integrated circuit of claim 1, wherein the single bit state variable represents one of: an ethernet link status and an ethernet activity status and the external state contact is operable to control a light emitting diode (LED).

4. The integrated circuit of claim 1, comprising a second selector for selecting to pass to a second external state contact either a second single-bit state variable or a second multi-bit state variable encoded into a second bit stream.

5. The integrated circuit of claim 1, wherein the multi-bit state variable provides information about an ethernet link training process to establish a network link between two single pair ethernet partners.

6. The integrated circuit of claim 1, wherein the multi-bit state variable provides information about an equalization state machine for configuring an equalizer circuit to modify a transmission signal to be output on the external communications contact.

7. The integrated circuit of claim 1, comprising an interrupt signal pin.

8. A method comprising:
tracking state machine status information in a multi-bit state variable within an integrated circuit;
encoding the multi-bit state variable into a bit stream;
tracking a single-bit state variable, the single bit state variable representing a present state of a network physical interface;
selecting the bit stream to output on a light emitting diode (LED) contact of the integrated circuit during a period of link startup;
selecting the single-bit state variable to output on the first LED contact of the integrated circuit after the period of link startup; and
alternately transmitting and receiving data on the network physical interface.

9. The method of claim 8, comprising:
concurrently:
decoding the bit stream with one of: an oscilloscope, a digital logic analyzer, and a general-purpose input to a processor external to the integrated circuit; and
observing a data signal on the network physical interface.

10. The method of claim 8, wherein the multi-bit state variable indicates one of: a current test pattern transmitted on the network physical interface and a current equalizer configuration and the single-bit state variable indicates one of: an ethernet link status and an ethernet activity status.

11. The method of claim 8, comprising:
encoding a second multi-bit state variable into a second bit stream;
tracking a second single bit state variable, the second single bit state variable representing a second present state of the network physical interface;
selecting the second bit stream to output on a second LED contact of the integrated circuit during the period of link startup; and
selecting the second single-bit state variable to output on the second LED contact of the integrated circuit after the period of link startup.

12. The method of claim 11, wherein the second single-bit state variable represents one of: an ethernet link status and an ethernet activity status.

13. The method of claim 8, wherein the multi-bit state variable provides information about an ethernet link training process to establish a network link between two single pair ethernet partners.

14. The method of claim 8, comprising driving an interrupt pin of the integrated circuit to initiate a debug mode of operation.

15. A circuit comprising:
an integrated circuit comprising:
a state machine including a multi-bit state variable and a single-bit state variable, the single-bit state variable representing a present state of a local area network (LAN) physical interface,
an encoder to encode the multi-bit state variable into a bit stream,
a first selector for selecting to pass to an external state pin either the single-bit state variable or the bit stream based on a configuration value, and
an external pin for transmitting or receiving local area network (LAN) data; and
a printed circuit board comprising:
two contacts for connecting a light emitting diode (LED), the first contact coupled to the external state pin and the second contact coupled to a resistor, and
a network connector communicatively coupled to the external pin for transmitting or receiving LAN data.

16. The circuit of claim 15, wherein the first contact is coupled to a digital logic analyzer for decoding the bit stream.

17. The circuit of claim 15, wherein the single bit state variable represents one of: an ethernet link status and an ethernet activity status.

18. The circuit of claim 15, the integrated circuit comprising a second selector for selecting to pass to a second external state pin either an output of the first selector or an operational status indicator to an external pin based on a second configuration value.

19. The circuit of claim 18, wherein the second external state pin is operable to control a light emitting diode (LED) indicating one of: an ethernet link status and an ethernet activity status.

20. The circuit of claim 15, wherein the multi-bit state variable provides information about an ethernet link training process to establish a network link between two single pair ethernet partners.
